(19) United States
(12) Patent Application Publication
(10) Pub. No.: US 2010/0202119 A1
(43) Pub. Date: Aug. 12, 2010

(54) STRUCTURE FOR FIXING FLEXIBLE WIRING BOARD

(75) Inventors: Tetsuro Nagami, Tokyo (JP); Shinji Serizawa, Tokyo (JP); Yoichi Yasui, Tokyo (JP)

Correspondence Address: BIRCH STEWART KOLASCH & BIRCH, PO BOX 747, FALLS CHURCH, VA, 22040-0747, US

(73) Assignee: MITSUBISHI ELECTRIC CORPORATION, Tokyo (JP)

(21) Appl. No.: 12/668,835

(22) PCT Filed: Jun. 2, 2008
(86) PCT No.: PCT/JP2008/001389

§ 371 Date: Jan. 12, 2010

(30) Foreign Application Priority Data
Sep. 21, 2007 (JP) 2007-245595

(51) Int. Cl. H05K 1/14

(52) U.S. Cl. 361/749

(57) ABSTRACT

A flexible wiring board 1 includes an insulating member 12 having a conductor 11 formed therein, a reinforcing board 13 for reinforcing the insulating member 12 in the vicinity of the connection terminal 11a of the flexible wiring board 1, and a lock member 14 to be locked to a board 3 having a connector 2, with the board 3 having an opening 31 for receiving the lock member 14 fit therein in a state where the connection terminal 11a is connected and secured to the connector 2.

### TECHNICAL FIELD

The present invention relates to a fixing structure of a flexible wiring board (FPC) for establishing an electric connection between electronic components or circuit boards.

### BACKGROUND ART

Conventionally, in the connection using a flexible wiring board (flexible printed circuit board, hereinafter referred to as an “FPC”), when an FPC is inserted into a connector provided on an electronic component or a circuit board and fixed thereto, the FPC is sometimes fixed thereto with the FPC curved or with the FPC inserted insufficiently into the interior of the connector, and thus the FPC occasionally causes failure in an apparatus using the FPC. For preventing such failures, e.g., in Patent Document 1, an FPC has integrally formed a square-frame-shaped guide made of a flexible insulating member such that the guide encloses the periphery of the exposed ends of conductors which are provided in a row on the FPC. The guide is provided, around the periphery of the exposed ends of the conductors, with a U-shaped slot, and the positioning of the FPC is performed by using the end face of the slot and the end face of a connector provided on the side of an apparatus to be connected, thus preventing insufficient insertion of the FPC.

Patent Document 1: JP-A-2003-217719

Since the conventional fixing structure of an FPC is arranged as described above, the end face of the connector is short in an inserting direction of the FPC. Further, since the connector is provided with a pawl for locking the FPC thereto, the area of the end face thereof where positioning is possible is limited. Thus, there is a problem that accurately positioning of the FPC is difficult. Moreover, the guide is provided so as to enclose the exposed portion of the conductors of an FPC, and thus there is a problem that, when the FPC is inserted into the connector, the guide abuts against the connector before the terminal section of the conductors abuts again the connector, thus deteriorating the workability. Furthermore, when a force is exerted on the FPC in a pulling out direction of the FPC from the connector, the FPC is easily deformed, and thus there is a problem that the guide cannot function as a retainer for the FPC.

The present invention has been made to solve the above-mentioned problems, and an object of the present invention is to provide a fixing structure of a flexible wiring board for facilitating the accurate positioning of an FPC to a connector without deteriorating workability and also for preventing the FPC from being unintentionally disconnected from the connector.

### DISCLOSURE OF THE INVENTION

The fixing structure of a flexible wiring board according to the present invention is the one for connecting and securing a terminal section at the end of the flexible wiring board to a connector provided on a stationary board, wherein the flexible wiring board is composed of an insulating member having a wiring pattern formed thereon, a reinforcing member for reinforcing the insulating member in the vicinity of the terminal section, and a lock member for locking the flexible wiring board to the stationary board, such that the stationary board has an opening for receiving and fitting the lock member to be fit therein in a state where the terminal section thereof is connected and secured to the connector thereof.

According to the present invention, it is arranged that the flexible wiring board is provided with the lock member, wherein the lock member is fit in the opening of the stationary board in a state where the terminal section of the flexible wiring board is connected and secured to the connector. Thus, the flexible wiring board can be accurately positioned. Further, the flexible wiring board can be prevented from being inserted therein in an incomplete shape and also the flexible wiring board can be prevented from being unintentionally disconnected from the connector.

### BRIEF DESCRIPTION OF THE DRAWINGS

FIG. 1 is a front view showing a composition of a fixing structure of an FPC in accordance with the first embodiment of the present invention.

FIG. 2 is a perspective view showing operations for fixing an FPC in accordance with the first embodiment of the present invention.

FIG. 3 is a front view showing a composition of a fixing structure of an FPC in accordance with the second embodiment of the present invention.

FIG. 4 is a perspective view showing a fixed state of an FPC in accordance with the second embodiment of the present invention.

FIG. 5 is a front view showing a composition of an FPC in accordance with the third embodiment of the present invention.

FIG. 6 is a view showing a fixed state of an FPC in accordance with the third embodiment of the present invention.

FIG. 7 is a front view showing a composition of a fixing structure of an FPC in accordance with the fourth embodiment of the present invention.

FIG. 8 is a view showing a fixed state of an FPC in accordance with the fourth embodiment of the present invention.

FIG. 9 is a view showing a composition of a fixing structure of an FPC in accordance with the fourth embodiment of the present invention.

FIG. 10 is a view showing a composition of a fixing structure of an FPC in accordance with the fifth embodiment of the present invention.

FIG. 11 is a view showing a composition of a fixing structure of an FPC in accordance with the fifth embodiment of the present invention.

### BEST MODE FOR CARRYING OUT THE INVENTION

In order to explain the present invention in more detail, the best embodiments of the present invention will be described below, with reference to the accompanying drawings.

### First Embodiment

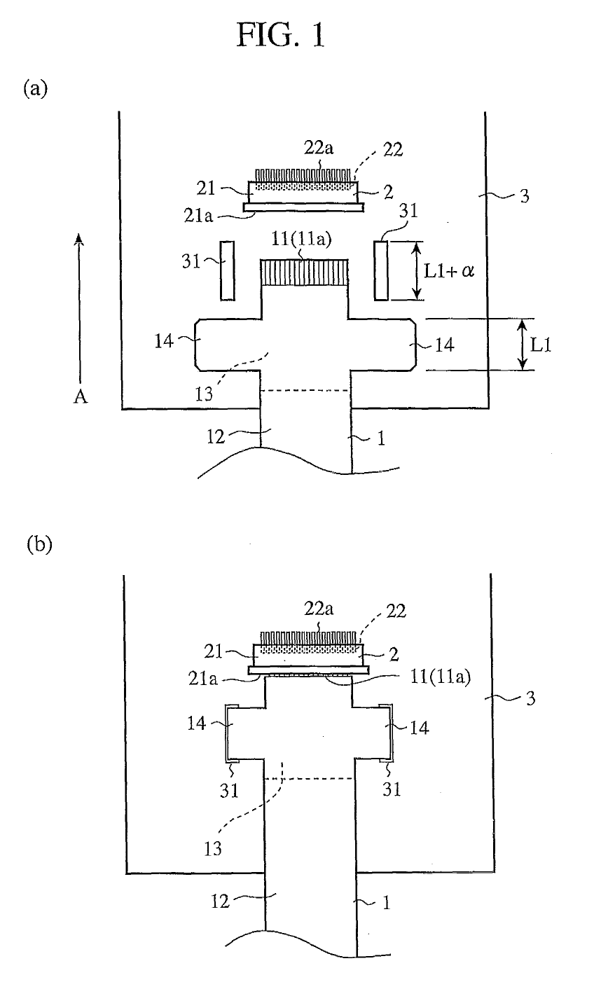

FIG. 1 is a front view showing a composition of a fixing structure of an FPC in accordance with the first embodiment of the present invention, FIG. 1(a) is a view showing a state before an FPC is fixed, and FIG. 1(b) is a view showing a state after an FPC has been fixed. An FPC (flexible wiring board) 1 is composed of a conductor 11, an insulating member 12, and a reinforcing board (reinforcing member) 13, and inserted into a connector 2 provided on a board (stationary board) 3 to be electrically connected with the board 3. The conductor 11 as a wiring pattern is disposed within the flexible insulating member 12; however, at the one end of the FPC 1, the insulating member 12 is striped to expose the conductor 11, thus forming a connection terminal section 11a to be connected to the connector 2. Further, the insulating member 12 has a pair of rectangular lock members 14 projecting in a substantially orthogonal direction to the direction of inserting the FPC 1 into the connector 2, as indicated by arrow A in FIG. 1.

The FPC is provided, on the backside of the vicinity of the connection terminal section 11a and the lock member 14, with an insulating reinforcing board 13 integrally bonded thereto. By providing the reinforcing board 13, the strength of the connection terminal section 11a is increased, thus facilitating the connection between the FPC 1 and the connector 2, and also the strength of the lock member 14 is enhanced, thus stabilizing the fixation of the FPC 1 to the board 3. Thus, the lock member 14 is composed of the insulating member 12 and the reinforcing board 13. In this context, both the corners at the tip of the lock member 14 may be chamfered or rounded.

The connector 2 includes an insulator 21 and a connection terminal 22. Formed at one end of the insulator 21 is a fitting hole 21a for receiving the connection terminal section 11a of the FPC 1 to be inserted and fit therein. The connection terminal 22 is formed inside the other end of the insulator 21, and is connected with the connection terminal section 11a of the FPC inserted and fit in the fitting hole 21a. Moreover, the connection terminal 22 has an exposed terminal 22a exposed from the rear side of the other end of the insulator 21, and by connecting the exposed terminal 22a to a wiring pattern (not shown) on the board 3 by soldering, the connector 2 is mounted on the board 3.

The board 3 is provided, at two places thereof, with rectangular openings 31 for receiving the lock members 14 of the FPC 1 to be passed therethrough and locked thereto. When the connection terminal section 11a of the FPC 1 is inserted and fit in the connector 2 from the direction of arrow A, the lock members 14 of the FPC 1 are arranged to be located above the respective openings 31 provided at the two places thereof. To be more exact, in this structure, in the event where the connection terminal section 11a has not been completely fit in the interior of the connector 2, the lock members 14 cannot be inserted into the openings 31; thus the FPC 1 is prevented from being inserted therein in an incomplete shape or inserted therein from a diagonal direction. As shown in FIG. 1(a), the opening 31 is formed in a rectangular shape longitudinal in the direction of arrow A in accordance with the shape of each of the lock members 14 to be passed therethrough, and assuming that the length, in the traverse direction of the lock member 14, of the lock member is L1, the length, in the longitudinal direction, of the opening 31 is arranged to satisfy a requirement of L1+α.

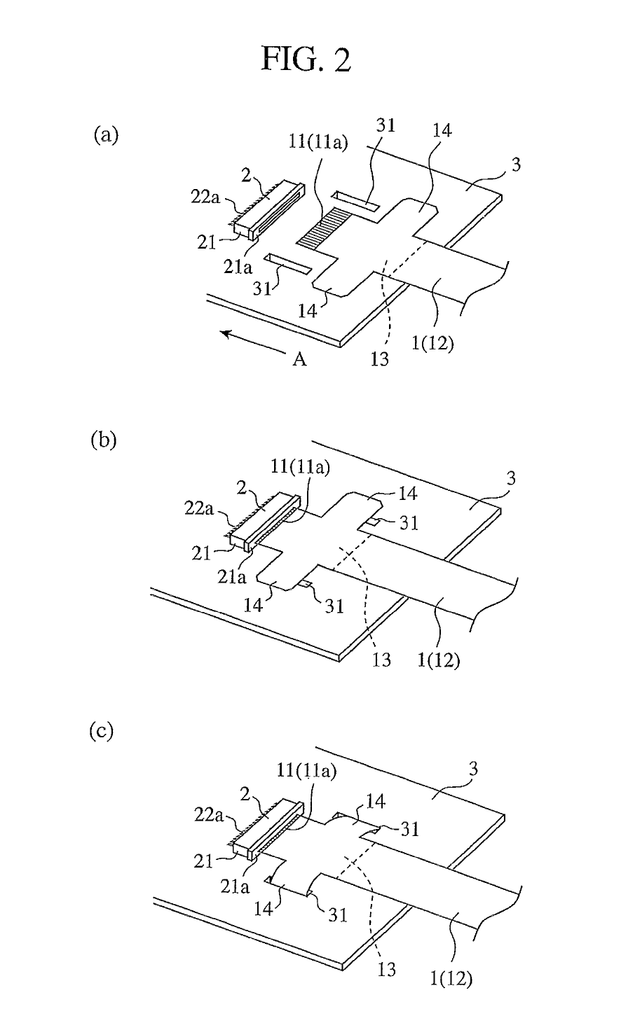

Next, operations for inserting the FPC 1 into the connector 2 and fixing the FPC 1 on the board 3 are as follows: FIG. 2 is an oblique view showing operations for inserting an FPC thereinto according to the present invention.

As shown in FIG. 2(a) and FIG. 2(b), the FPC 1 is inserted into the fitting hole 21a of the connector 2 from the direction of arrow A to connect the connection terminal section 11a provided at the tip of the FPC 1 to the connection terminal 22 disposed inside the connector 2. At this time, as shown in FIG. 2(b), the lock members 14 of the FPC 1 are arranged to be located above the respective openings 31 provided through the board 3. Then, as shown in FIG. 2(c), the lock members 14 are inserted into the respective openings 31 while bending the members toward the board 3. When each of the lock members 14 is chamfered or rounded at both corners of the tip thereof, the chamfered surface or rounded surface (C-surface or R-surface) guides the insertion of the lock member 14 into the opening 31, thus facilitating the insertion. Thus, by inserting the lock member 14 into the opening 31 to fix the FPC 1 on the board 3, the FPC 1 can be prevented from moving horizontally and vertically to the board 3.

As discussed above, the fixing structure of an FPC in accordance with the first embodiment is arranged such that the lock member is formed using the insulating member and the reinforcing member of the FPC and the lock member is passed through the opening provided through the board, and thus the FPC can be prevented from moving horizontally and vertically to the board. Furthermore, the FPC can be prevented from unintentionally disconnected from the connector.

Moreover, the fixing structure of an FPC in accordance with the first embodiment is arranged such that, when the FPC is fit into the connecter, the lock members are located above the respective openings provided through the board, and thus the positioning of the FPC can be accurately performed. Further, in this structure, when the FPC is not completely fit in the connector, the lock members cannot be inserted therein, and thus the FPC can be prevented from being inserted into the connector in an incomplete shape or from a diagonal direction.

In addition, the fixing structure of an FPC in accordance with the first embodiment is arranged such that each of the lock members 14 is chamfered or rounded at both corners of the tip thereof, and thus those chamfered or rounded surfaces can guide the insertion of the lock member into the opening to facilitate the insertion and improve the workability thereof.

### Second Embodiment

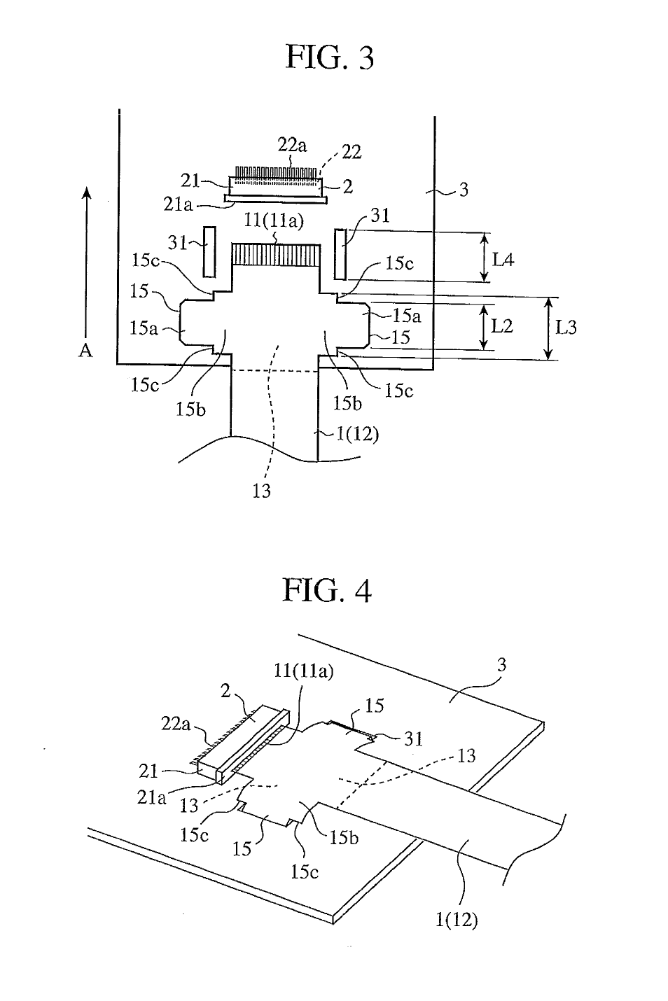

FIG. 3 is a front view showing a composition of a fixing structure of an FPC in accordance with the second embodiment of the present invention.

In this fixing structure, an FPC has a shoulder portion wider than the width of the tip portion of a lock member in the basal portion of each of the lock members which is explained in the fixing structure of an FPC in accordance with the first embodiment shown in FIG. 1. Hereinbelow, to the same parts as the constituent elements of the fixing structure of an FPC in accordance with the first embodiment, the same numerals as those used in the first embodiment are provided and its explanation are omitted or simplified.

An FPC 1 is composed of a conductor 11, an insulating member 12, and a reinforcing board 13. The insulating member 12 and the reinforcing board 13 has a pair of lock members 15 projecting in a generally orthogonal direction to the direction of arrow A indicating the inserting direction of the FPC 1 into the connector 2, and further, each of the lock members 15 has formed in the basal portion thereof a shoulder portion 15b wider than the width of the tip portion 15a thereof. By providing the shoulder portion 15b, the tip portion 15a is provided, on each side thereof, with an abutting section 15c. Assuming that, as shown in FIG. 3, the width in the longitudinal direction of the tip portion 15a is L2 and the width in the longitudinal direction of the shoulder portion 15b is L3, the opening 31 provided through the board 3 is arranged such that the width thereof in the longitudinal direction L4 satisfies a requirement of L2+α<L4<L3. Thus, the shoulder portion 15b is arranged such that the width L3 thereof is larger than the width L4 of the opening 31, and thus the abutting sections 15c of the shoulder portion 15b abut against the upper surface of the board 3, restricting the amount of insertion of the lock member 15.

Next, operations for inserting the FPC 1 into the connector 2 and fixing the FPC 1 on the board 3 are as follows: FIG. 4 is an perspective view showing a fixed state of an FPC in accordance with the second embodiment of the present invention.

The FPC 1 is inserted into the connector 2 to connect the terminal section 11a provided at the tip of the FPC 1 to the connection terminal 22 provided inside the connector 2. At this time, the lock members 15 of the FPC 1 are located above the respective openings 31 provided through the board 3. Then, when the tip portions 15a of the lock members 15 are passed through the respective openings 31 while bending the members toward the board 3, the abutting sections 15c of the lock member 15 abut against the upper surface of the board 3 to regulate the amount of insertion of the lock member 15.

The tip portion 15a of the lock member 15 is provided, on each side thereof, with an abutting section 15c, and thus the two abutting sections 15c abut against the board 3, respectively, preventing the FPC 1 from being twisted, thus stabilizing the positional relation between the FPC 1 and the connector 2. Further, even when a strong force enough to break the FPC 1 is exerted on the FPC 1, stresses concentrate at the vicinity of the abutting section 15c and the breakage occurs in the vicinity of the abutting portion 15c. For this reason, the impact of the breakage can not reach the conductor 11 including the wiring pattern, and occurrence of troubles such as contact failure and the like to the connector 2 can be restrained. Moreover, the lock member 15 may be chamfered or rounded at both corners of the tip thereof as with the first embodiment.

As discussed above, the fixing structure of an FPC in accordance with the second embodiment is arranged such that the lock member is formed using the insulating member and the reinforcing member, further the lock member is provided, in the basal portion thereof, with the shoulder portion wider than the width of the tip portion thereof, and also the shoulder portion is provided with the abutting sections. Thus, the abutting section abuts against the upper surface of the board, restricting the amount of insertion of the lock member into the opening and also preventing the FPC from being twisted. Besides, when a force is exerted on the FPC, stress concentrates at the vicinity of the abutting section, and thereby occurrence of the breakage of the conductor and contact failure or the like to the connector can be restrained.

### Third Embodiment

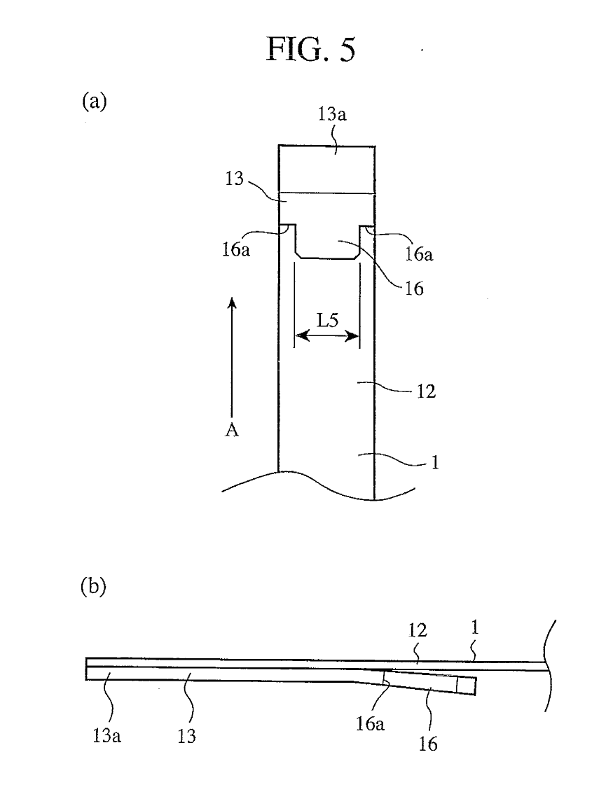

FIG. 5 is a view showing a composition of an FPC in accordance with the third embodiment of the present invention, FIG. 5(a) is a front view showing the composition of the back of the FPC, and FIG. 5(b) is a side view thereof.

In the fixing structure of an FPC, a lock member projecting from the end of a reinforcing board in the inserting direction of an FPC is employed, instead of the lock member of the fixing structure of an FPC in accordance with the first embodiment shown in FIG. 1 projecting from the insulating member and the reinforcing member in a direction substantially orthogonal to the inserting direction of the FPC. Hereinbelow, to the same parts as the constituent elements of the fixing structure of an FPC in accordance with the first embodiment, the same numerals as those used in the first embodiment are provided and their explanations are omitted or simplified.

An insulating reinforcing board 13 is bonded in the vicinity of the connection terminal section 11a of an FPC 1. In the first embodiment, the reinforcing board 13 is arranged so as to be bonded integral to the insulating member 12; however, in the third embodiment, one end of the reinforcing board 13 forms a bonded portion 13a where the board is bonded and secured to the insulating member 12, while the other end of the reinforcing board 13 is not bonded and secured to the insulating member 12 but provided with a lock member 16 projecting in the direction of arrow A indicating the insertion or withdrawal direction of the FPC 1 into or from the connector 2. In such a way, since the reinforcing board 13 is not bonded and secured to the insulating member 12 except for the bonded portion 13a, it is possible to curve the lock member 16 from the FPC 1 to separate the member therefrom as shown in FIG. 5(b). Further, an abutting section 16a is formed on each side of the lock member 16, and the abutting section 16a abuts against the upper surface of the board 3 to thus restrict the amount of insertion of the lock member 16. In addition, the lock member 16 may be chamfered or rounded at both the corners of the tip thereof.

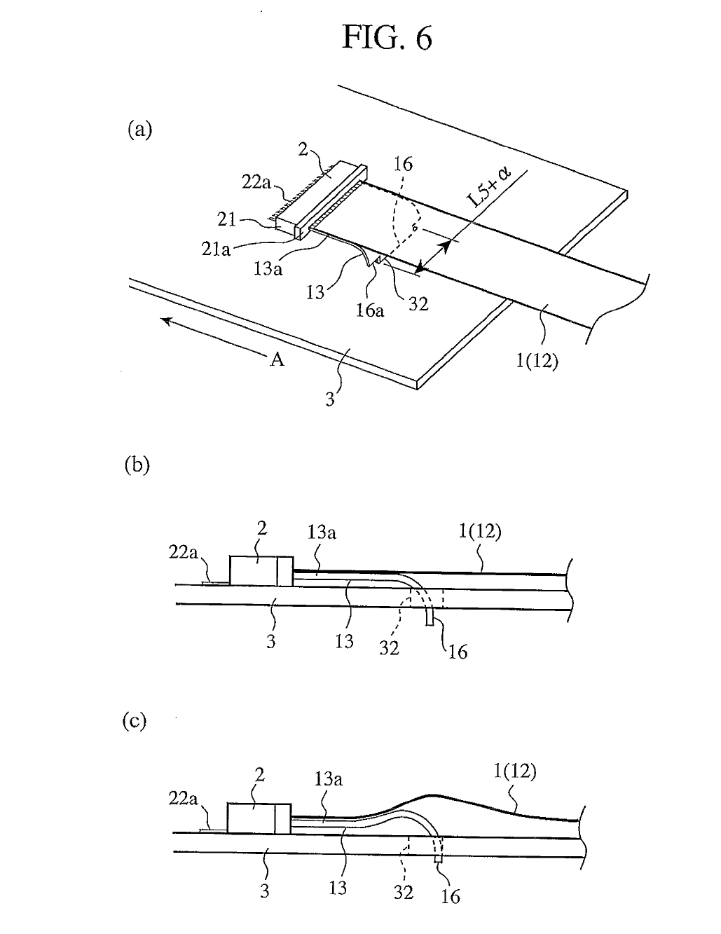

FIG. 6 is a view showing a fixed state of an FPC in accordance with the third embodiment of the present invention, FIG. 6(a) is a perspective view at the time when the FPC is fixed, and FIG. 6(b) is a side view thereof.

The board 3 is provided with a rectangular opening 32 for receiving the lock member 16 of the FPC 1 to be passed therethrough and locked thereto. When the connection terminal section 11a of the FPC 1 is inserted and fit in the connector 2 from the direction of arrow A, the lock member 16 of the reinforcing board 13 is arranged to be located above the opening 32. To be concrete, in this structure, in the event that the connection terminal section 11a of the FPC has not been completely fit within the connector 2, the lock member 16 cannot be inserted into the opening 32, thus preventing the FPC 1 from being inserted therein in an incomplete shape or inserted therein from a diagonal direction.

Moreover, as shown in FIG. 6(a), the opening 32 is formed in a rectangular shape extending in the direction substantially orthogonal to the direction of arrow A indicating the inserting direction of the FPC 1 into the connector 2 to conform to the shape of the lock member 16 to be passed therethrough, and arranged so that when the width in the longitudinal direction of the lock member 16 is assumed to be L5, the width in the longitudinal direction of the opening 32 may satisfy a requirement of L5+α.

Next, referring now to FIG. 6, operations for inserting the FPC 1 into the connector 2 and fixing the FPC 1 on the board 3 will be discussed.

The FPC 1 is inserted into the connector 2 to connect the terminal section 11a provided at the tip of the FPC 1 to the connection terminal 22 disposed inside the connector 2. At this time, the lock member 16 of the reinforcing board 13 is located above the opening 32 provided through the board 3. Subsequently, when the lock member 16 is inserted into the opening 32 while bending the member toward the board 3, the abutting sections 16a of the lock member 16 abut against the top of the board 3 to restrict the amount of insertion of the lock member 16.

The abutting section 16a is formed on each side of the lock member 16 is provided; thus, the two abutting sections 16a abut against the board 3, preventing the FPC 1 from being twisted and stabilizing the positional relation between the FPC 1 and the connector 2.

FIG. 6(c) is a view showing a state where the FPC is inserted into the connector in an incomplete insertion state. When the FPC 1 has been inserted into the connector 2 in an imperfect state, a force is exerted on the FPC 1 in a disconnecting direction of the FPC 1, and flexure occurs in the FPC 1 as shown in FIG. 6(c). Thus, the presence or absence of abnormality in insertion can be visually confirmed. Further, even when a force is mistakenly exerted on the FPC 1 in a direction pulling out the FPC 1 from the connector 2 in an assembly, the abutting portions 16a abut against the upper surface of the board 3 to thereby cause a flexure in the FPC 1; thus, such an imperfect insertion can be visually confirmed.

As discussed above, the fixing structure of an FPC in accordance with the third embodiment is arranged such that the insulating member is provided, on the back thereof, with the reinforcing board having the lock member insertable in the opening provided through the board; moreover, one end of the reinforcing board is bonded to the insulating member, while the other end thereof is attached separably to the insulating member. In this way, the FPC can be fixed on the board with only the reinforcing board when the FPC is fixed thereon, and the conductor and the insulating member can be prevented from being damaged because of the contact with the board. Furthermore, if there is any abnormality in the insertion of the FPC, a flexure is caused in the FPC, and thus the abnormality can be visually found.

Furthermore, the fixing structure of an FPC in accordance with the third embodiment is arranged such that the lock member is provided, on each side thereof, with the abutting section, and thus, the abutting sections abut against the upper surface of the board, thereby restricting the amount of insertion of the lock member into the opening and also preventing the FPC from being twisted.

### Fourth Embodiment

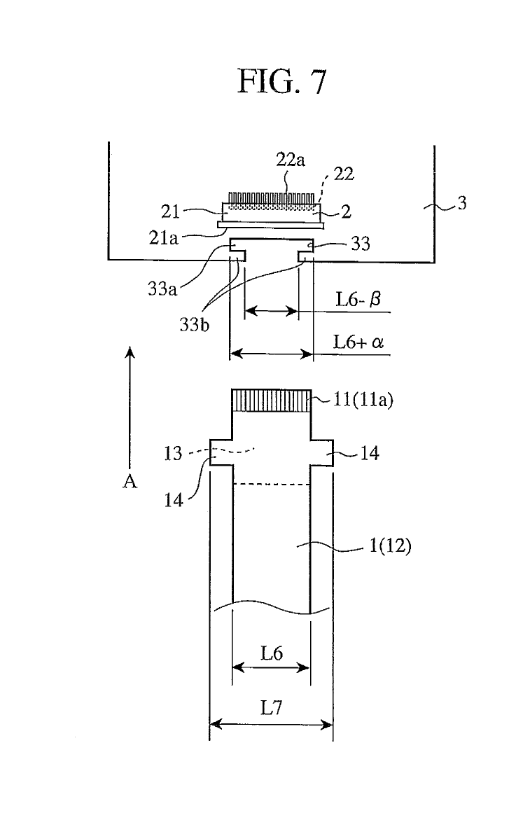

FIG. 7 is a front view showing a composition of a fixing structure of an FPC in accordance with the fourth embodiment of the present invention.

In the fixing structure of an FPC, an opening to communicate with the exterior by partially cutting away the edge of the board is employed, instead of the opening provided in the board of the fixing structure of a FPC in accordance with the first embodiment shown in FIG. 1. Hereinafter, to the same parts as the constituent elements of the fixing structure of an FPC in accordance with the first embodiment, the same numerals as those used in the first embodiment are provided and their explanations are omitted or simplified.

As shown in FIG. 7, an FPC 1 consists of a conductor 11, an insulating member 12, a reinforcing board 13, and a pair of lock members 14 as with the first embodiment. The connector 2 is disposed in the vicinity of the outer peripheral portion of the board 3. The board 3 is provided with a generally T-shaped opening 33 to communicate with the exterior by partially cutting away the edge of the board on the side where the FPC 1 is inserted or withdrawn into or from the connector 2. Further, the opening 33 can receive the FPC 1 passed therethrough, and the lock members 14 abut against the upper surface of the board 3. The opening 33 is composed of an insertion section 33a for receiving the FPC 1 passed therethrough and two opposing lock pieces 33b for locking the FPC 1 thereon. Additionally, assuming that the width, in the traverse direction, of the FPC 1 is L6, the opening is arranged to satisfy a requirement that the width in the longitudinal direction of the insertion section 33a is L6+α and the width of an opened section formed between the two lock pieces 33b is L6−β. Moreover, when the width, in the traverse direction, of the FPC 1 including the lock members 14 is assumed to be L7, the fixing structure of the FPC satisfies a requirement of L7>L6+α.

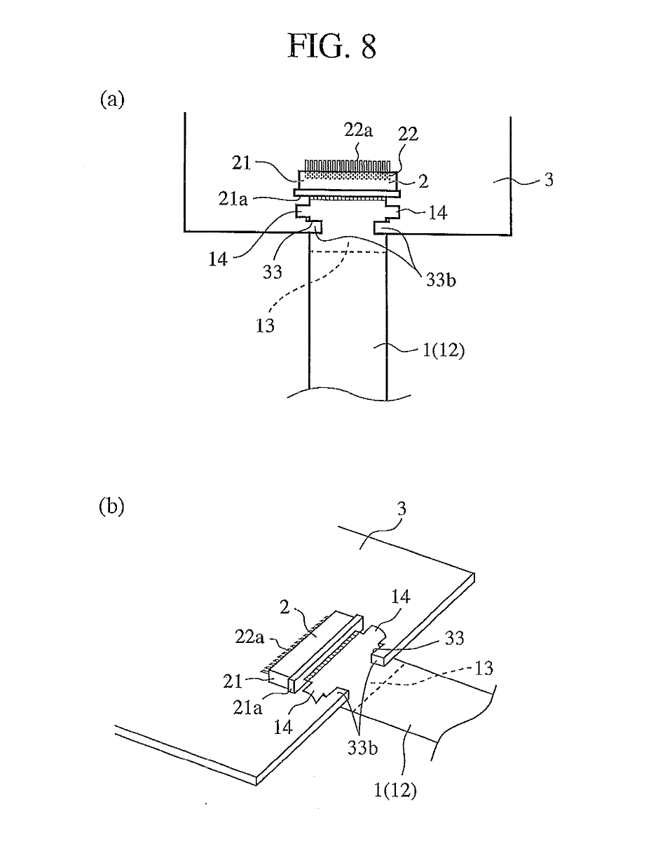

Next, operations for inserting the FPC 1 into the connector 2 and fixing the FPC 1 on the board 3 are as follows: FIG. 8 is a view showing a fixed state of an FPC in accordance with the fourth embodiment of the present invention, FIG. 8(a) is a front view at the time when the FPC is fixed, and FIG. 8(b) is a perspective view thereof.

The FPC 1 is inserted into the fitting hole 21a of the connector 2 to connect the connection terminal section 11a of the FPC 1 to the connection terminal 22 provided inside the connector 2. Subsequently, in a state that the lock members 14 of the FPC 1 is located above the board 3, the portion lower than the lock member 14 of the FPC 1 is passed through the opened section formed between the two lock pieces 33b of the opening 33. In such a way, the lock members 14 abut against the upper surface of the board 3 to prevent the FPC 1 from being disconnected from the connector 2. Moreover, the lock members 14 abut against the upper surface of the board 3, and also the FPC 1 is locked by the two lock pieces 33b of the board 3, thus preventing the FPC 1 from being twisted.

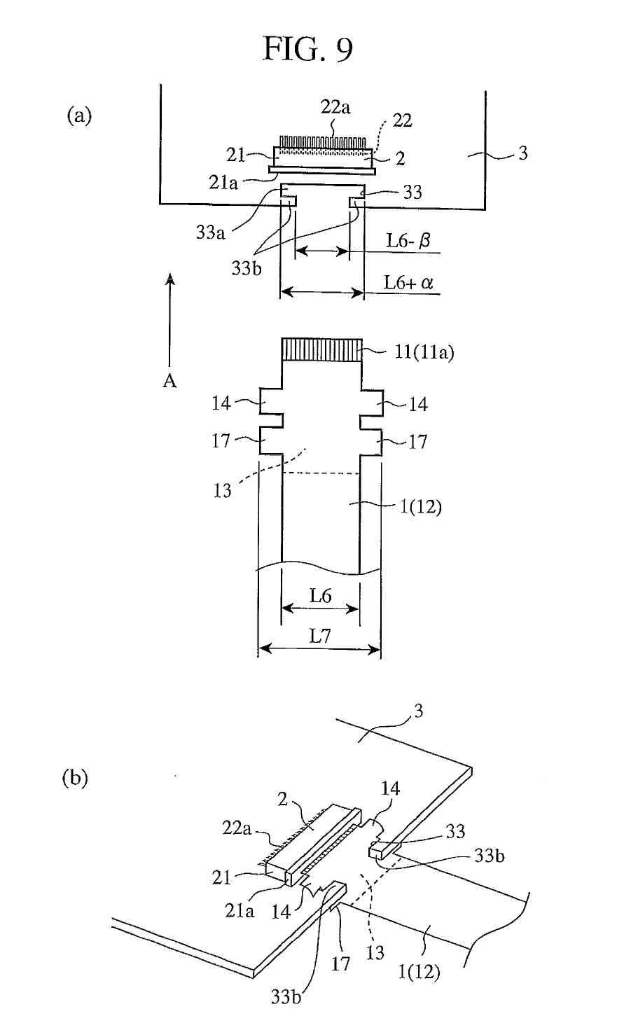

FIG. 9 is a view showing an another example of a fixing structure of an FPC in accordance with the fourth embodiment of the present invention. FIG. 9(a) is a front view showing a composition of the fixing structure, and FIG. 9(b) is a perspective view showing a fixed state of the FPC.

In the composition shown in FIG. 9, the FPC 1 has a pair of lock members (second lock members) 17 in addition to the lock members (first lock members) 14. The board 3 is provided, as with the embodiment shown in FIG. 8, with a substantially T-shaped opening 33 communicate with the exterior by partially cutting away the edge of the board 3, and the opening 33 is composed of the insertion section 33a and the lock pieces 33b. In addition, assuming that the width, in the traverse direction, of the FPC 1 is L6, the opening is arranged to satisfy a requirement that the width in the longitudinal direction of the insertion section 33a is L6+α and the width of the opened section formed between the two lock pieces 33b is L6−β. Further, when the width, in the traverse direction, of the FPC 1 including the lock members 14 and the lock members 17 is assumed to be L7, the fixing structure of the FPC satisfies a requirement of L7>L6+α.

Next, operations for inserting the FPC 1 into the connector 2 and fixing the FPC 1 on the board 3 are as follows:

As shown in FIG. 9(b), the FPC 1 is inserted into the fitting hole 21a of the connector 2 to connect the connection terminal section 11a of the FPC 1 to the connection terminal 22 provided inside the connector 2. Then, the portion lower than the lock members 14 and upper than the lock members 17 of the FPC 1 is passed through the opened section formed between the two lock pieces 33b such that the lock members 14 of the FPC 1 are located above the board 3 and the lock members 17 are located below the board 3. In this way, the lock members 14 abut against the upside of the board 3, while the lock member 17 abuts against the underside of the board 3. Thus, the FPC 1 can be prevented from being wrongly pulled out from the connector 2, and also the FPC 1 can be prevented from receiving an excessive force exerted thereon in the inserting direction thereof. Moreover, the lock members 14 and the lock members 17 abut against the board 3, and at the same time the FPC 1 is locked by the two lock pieces 33b of the board 3, thus preventing the FPC 1 from being twisted.

As described above, the fixing structure of an FPC in accordance with the fourth embodiment is arranged such that the opening to communicate with the exterior by partially cutting away the edge of the board and the FPC is passed through the opening to be fixed therein. Thus, even when the connector is disposed in the vicinity of the periphery of the board and the distance from the connector to the peripheral portion of the board is short, the FPC can be surely secured.

Further, the fixing structure of an FPC in accordance with the fourth embodiment is arranged such that the FPC is passed through the opening to communicate with the exterior by partially cutting away the edge of the board and the lock members of the FPC are caused to abut against the upper side of the board. Thus, the FPC connected to the connector can be prevented from being pulled out therefrom. Furthermore, the FPC can be prevented from being twisted.

Moreover, the fixing structure of an FPC in accordance with the fourth embodiment is arranged such that the opening is provided with the two lock pieces opposing to each other, and thus the FPC passed through the opening is locked by the lock pieces, preventing the FPC to be prevented from being twisted.

Additionally, the fixing structure of an FPC in accordance with the fourth embodiment is arranged such that the FPC is provided with the two pairs of lock members, one pair of lock members are located on the upside of the board, and the other pair of lock members are located on the downside of the board. Thus, the FPC connected to the connector can be prevented from being wrongly pulled out therefrom, and at the same time the FPC can be prevented from having an excessive force exerted thereon in the inserting direction thereof, preventing the connector from being damaged. Besides, the FPC can be prevented from being twisted.

### Fifth Embodiment

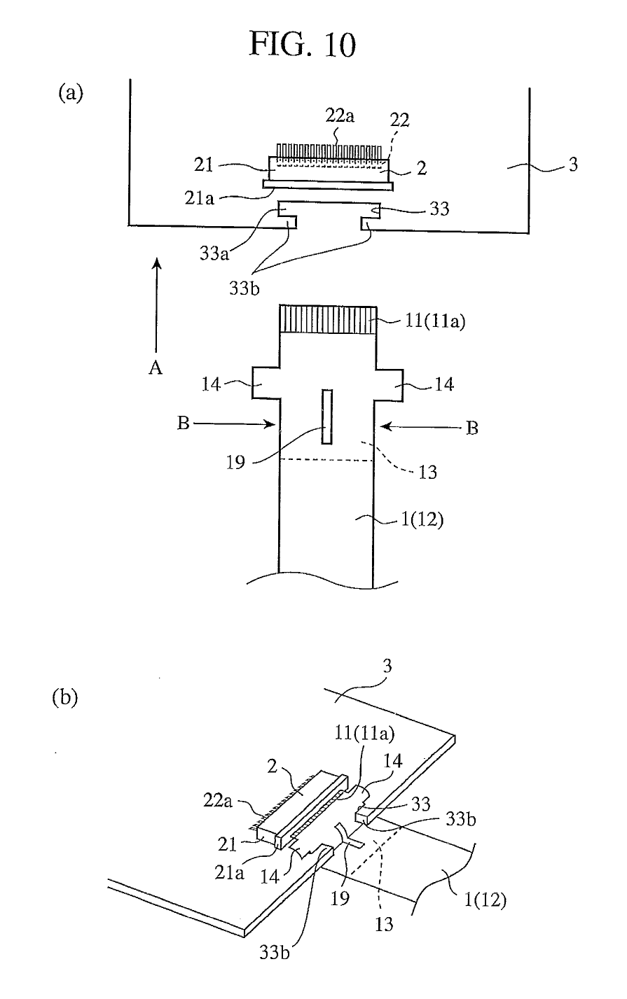

FIG. 10 is a view showing a composition of a fixing structure of an FPC in accordance with the fifth embodiment of the present invention. FIG. 10(a) is a front view showing a composition of the fixing structure, and FIG. 10(b) is a perspective view showing a fixed state of the FPC.

The fixing structure of the FPC has a hole additionally formed in the center of the FPC in the fixing structure of an FPC in accordance with the fourth embodiment shown in FIG. 7. Hereinlater, to the same parts as the constituent elements of the fixing structure of an FPC in accordance with the fourth embodiment, the same numerals as those used in the fourth embodiment are provided and their explanations are omitted or simplified.

As shown in FIG. 10, an FPC 1 has a longitudinal hole 19 extending in the direction of arrow A that is the inserting direction of the FPC 1 into the connector 2, in the vicinity of the lock members 14 thereof. By pressing the sides of a portion where the hole 19 is formed in the direction of arrow B of FIG. 10, the FPC 1 becomes concaved to facilitate the insertion of the FPC into the board 3. The board 3 is provided with a substantially T-shaped opening 33 to communicate with the exterior by partially cutting away the edge of the board on the inserting or withdrawing side of the FPC 1 into or from the connector 2 as with the fourth embodiment. The opening 33 consists of an insertion section 33a to receive the FPC 1 passed therethrough and two opposing lock pieces 33b to lock the FPC 1 thereto.

Next, operations for inserting the FPC 1 into the connector 2 and fixing the FPC 1 on the board 3 are as follows:

As shown in FIG. 10(b), the FPC 1 is inserted into the fitting hole 21a of the connector 2 to connect the connection terminal section 11a of the FPC 1 to the connection terminal 22 provided inside the connector 2. Then, with the lock members 14 of the FPC 1 located above the board 3, the portion lower than the lock members 14 of the FPC 1 is passed through the opened section formed between the two lock pieces 33b of the opening 33. At that time, the FPC 1 is passed through the opened section between the lock pieces 33b while depressing the FPC 1 by pressing the sides of a portion where the hole 19 is formed in the direction of arrow B. Thereby, operation for passing the FPC through the opened section between the lock pieces 33b is facilitated.

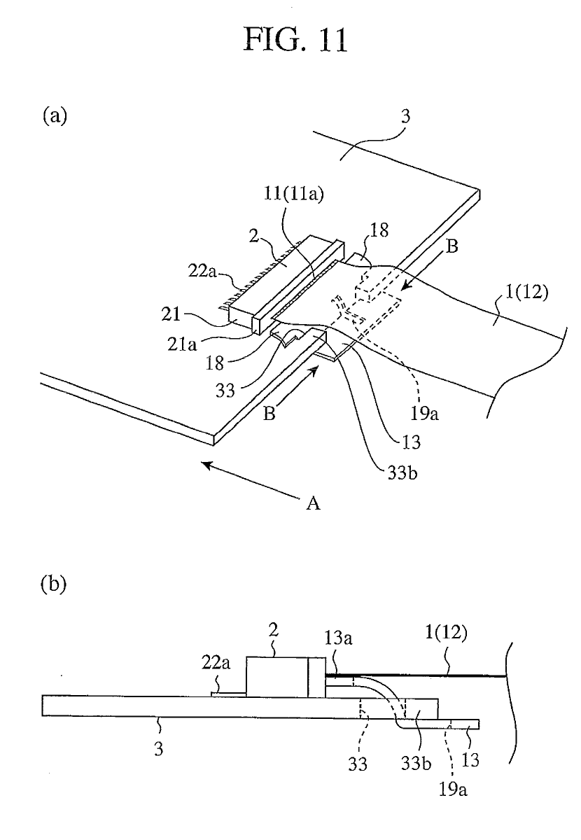

FIG. 11 is a view showing another example of a fixing structure of an FPC in accordance with the fifth embodiment of the present invention. FIG. 11(a) is a perspective view showing a composition of the fixing structure thereof, and FIG. 11(b) is a side view thereof.

In the composition shown FIG. 11, as with the reinforcing board 13 of the fixing structure of an FPC in accordance with the third embodiment shown in FIG. 6, the reinforcing board 13 is not bonded integral to the insulating member 12, one end of the reinforcing board 13 is bonded and fixed to the insulating member 12, and the other end thereof is arranged to be separable from the insulating member 12. In addition thereto, a hole 19a is additionally provided in the central portion of the reinforcing board 13.

As shown in FIG. 11(a), the FPC 1 is provided, in the vicinity of the connection terminal section 11a thereof, with an insulating reinforcing board 13 bonded thereto. One end of the reinforcing board 13 has a bonded portion 13a where the board is bonded and secured to the insulating member 12, and the other end of the reinforcing board 13 is not bonded and secured to the insulating member 12 and separated from the FPC 1 by being curved from the FPC 1. Moreover, the reinforcing board 13 is provided with lock members 18 projecting to the direction of arrow A that is the insertion or withdrawal direction of the FPC 1 into or form the connector 2, and further provided, in the vicinity of the lock members 18, with a rectangular hole 19a longitudinal in the direction of arrow A. By pressing the sides of the portion of the reinforcing board 13 where the hole 19a is formed, in the direction of arrow B of FIG. 11(a), the reinforcing board 13 becomes concaved to facilitate the insertion of the reinforcing board into the board 3. The board 3 is provided with a substantially T-shaped opening 33 to communicate with the exterior by partially cutting away the edge of the board on the inserting or withdrawing side of the FPC 1 into or from the connector 2 as with the fourth embodiment. The opening 33 is composed of an insertion section 33a to receive the reinforcing FPC1 passed therethrough and two opposing lock pieces 33b for locking the reinforcing FPC1 thereto.

Next, operations for inserting the FPC 1 into the connector 2 and fixing the FPC 1 on the board 3 are as follows:

As shown in FIG. 11(b), the FPC 1 is inserted into the fitting hole 21a of the connector 2 to connect the connection terminal section 11a of the FPC 1 to the connection terminal 22 provided inside the connector 2. Thereafter, with the lock members 18 of the reinforcing board 13 located above the board 3, the portion lower than the lock members 18 of the reinforcing FPC1 is passed through the opened section formed between the two lock pieces 33b of the opening 33. At this time, by pressing the sides of a portion of the reinforcing board 13 where the hole 19a is formed in the directions of arrow B, the reinforcing board 13 is passed through the opened section between the lock pieces 33b while depressing the reinforcing board 13. Thereby, the operation for passing the reinforcing board through the opened section between the lock pieces 33b is facilitated.

As discussed above, the fixing structure of an FPC in accordance with the fifth embodiment is arranged such that the FPC or the reinforcing board is provided with the hole, and thus the FPC or the reinforcing board can be passed through the opening provided through the board while pressing the side of the reinforcing board so as to be dented in the part where the hole is formed. Thereby, mounting of the FPC onto the board is facilitated to improve the workability thereof.

Besides, the fixing structure of an FPC in accordance with the fifth embodiment is arranged such that the insulating member is provided, on the back thereof, with the reinforcing board insertable in the opening provided through the board, and further, the reinforcing board is attached to the insulating member with one end thereof bonded to the member and with the other end thereof separated from the member. Thus, when the FPC is fixed on the board, it can be fixed thereon with only the reinforcing board, and therefore, the conductor and the insulating member can be prevented from being damaged because of the contact with the board.

Besides, in the fifth embodiment discussed above, the composition where the reinforcing board is provided with the hole is shown; however, if the reinforcing board can be passed through the opening without being depressed, the fixing structure of the FPC may be arranged without providing the hole therethrough.

It should be understood that in the first to fifth embodiments discussed above, the composition where a lock member is formed integral with an insulating member or a reinforcing board is shown; however, the fixing structure of the FPC may be arranged with a separate member. In addition, the composition where the lock member is formed in a rectangular shape is shown; however, the shape of the lock member is not limited to a rectangular one, and the lock member can have any other shape as long as it can perform the function of locking an FPC. Further, in the first, second, fourth, and fifth embodiments, the composition where the identically shaped lock members form a pair thereof is shown; however, the couple of lock members may be composed of nonidentically shaped or nonidentically sized ones.

### INDUSTRIAL APPLICABILITY

As discussed above, the fixing structure of a flexible wiring board according to the present invention is arranged such that a lock member is formed and the lock member is fit in the opening of a stationary board in a state where the terminal section of a flexible wiring board is connected and secured to a connector. Thus, the flexible wiring board can be accurately positioned, further the flexible wiring board can be prevented from being inserted into the connector in an incomplete shape, and also the flexible wiring board can be prevented from being disconnected unintentionally from the connector. Therefore, the fixing structure of a flexible wiring board is suitable for use, for example, in an apparatus using an FPC.

1-10. (canceled)

11. A fixing structure of a flexible wiring board for connecting and securing the terminal section of the end of the flexible wiring board to a connector provided on a stationary board,
wherein the flexible wiring board is composed of an insulating member having a wiring pattern formed thereon, a reinforcing member for reinforcing the insulating member in the vicinity of the terminal section, and a lock member for locking the flexible wiring board to the stationary board,
wherein the stationary board has an opening for receiving the lock member to be fit therein in a state where the terminal section is connected and secured to the connector,
wherein the lock member is made of the reinforcing member, and
wherein the reinforcing member is attached separably to the insulating member such that one end, in the insertion or withdrawal direction of the flexible wiring board of which the terminal section is connected to the connector, of the reinforcing member is bonded to the insulating member, while the other end thereof can fit in the opening of the stationary board.

12. A fixing structure of a flexible wiring board for connecting and securing the terminal section of the end of the flexible wiring board to a connector provided on a stationary board,
wherein the flexible wiring board is composed of an insulating member having a wiring pattern formed thereon, a reinforcing member for reinforcing the insulating member in the vicinity of the terminal section, and a lock member for locking the flexible wiring board to the stationary board,
wherein the stationary board has the opening to communicate with the exterior by partially cutting away the edge thereof on the side where the flexible wiring board is inserted or withdrawn, for receiving the flexible wiring board passed therethrough and causing the lock member to abut against the stationary board in a state where the terminal section is connected and secured to the connector, and
wherein the reinforcing member has the lock member projecting in a substantially orthogonal direction to the insertion or withdrawal direction of the terminal section thereof into or from the connector, and is attached separably to the insulating member such that one end in the insertion or withdrawal direction is bonded to the insulating member, while the other end thereof can fit in the opening of the stationary board.

13. The fixing structure of a flexible wiring board according to claim 12, wherein the flexible wiring board has, in the vicinity of the lock member, a hole extending in the insertion or withdrawal direction of the terminal section thereof into or from the connector.
